(19) United States
(12) Patent Application Publication
(10) Pub. No.: US 2026/0185771 A1
(43) Pub. Date: Jul. 2, 2026

(54) SUBSTRATE PROCESSING APPARTUS

(71) Applicant: SEMES CO., LTD., Cheonan-si (KR)

(72) Inventors: Hye Bin GWON, Cheonan-si (KR); Hyung Gyu KIM, Ansan-si (KR); Eun Seok KIM, Asan-si (KR); Seung Hoon OH, Cheonan-si (KR)

(73) Assignee: SEMES CO., LTD., Cheonan-si (KR)

(21) Appl. No.: 19/436,172

(22) Filed: Dec. 30, 2025

(30) Foreign Application Priority Data
Dec. 30, 2024 (KR) 10-2024-0200481

(51) Int. Cl. F26B 5/00; B08B 15/02; H10P 72/00

(52) U.S. Cl. CPC F26B 5/005; B08B 15/02; H10P 72/0408

(57) ABSTRACT

A substrate processing apparatus includes: a process chamber; and a filler member. The treatment space is defined by an upper surface, a bottom surface, and a side surface. The bottom surface includes: a lower central region in which a first supply port is formed to supply a supercritical fluid; a lower edge region disposed outside the lower central region and positioned higher than the lower central region; and a lower connection region positioned between the lower central region and the lower edge region. When viewed from above, the first supply port overlaps the filler member. The connection region includes a vortex generator that generates a vortex from the supercritical fluid while the supercritical fluid introduced between the filler member and the lower central region flows toward the lower edge region.

### CROSS-REFERENCE TO RELATED APPLICATION

This application claims priority to and the benefit of Korean Patent Application No. 10-2024-0200481 filed in the Korean Intellectual Property Office on Dec. 30, 2024, the entire contents of which are incorporated herein by reference.

### TECHNICAL FIELD

The present invention relates to an apparatus for processing a substrate, and more particularly, to a substrate processing apparatus including a process chamber processing a substrate by using a supercritical fluid.

### BACKGROUND ART

Semiconductor devices are manufactured through various processes including a deposition process, a photolithography process, and an etching process of forming a circuit pattern on a substrate, such as a silicon wafer. During this manufacturing process, various foreign substances, such as particles, organic contaminants, and metal impurities, remain on the wafer. Since these foreign substances cause defects in the substrate, they act as a factor that directly affects the yield of the semiconductor device. Therefore, in the semiconductor manufacturing process, a cleaning process for removing such foreign substances is essentially accompanied.

In general, the cleaning process includes chemical liquid treatment, rinsing treatment, and drying treatment. Recently, in order to prevent the pattern on the substrate from collapsing during the rinsing treatment, drying treatment is performed using a supercritical fluid.

A typical drying device supplies a supercritical fluid at a lower position than the support unit while the substrate is placed on the support unit. The supply port is formed at a position overlapping the support unit when viewed from above.

FIG. 1 is a diagram schematically illustrating the flow of a supercritical fluid in a general drying chamber.

Referring to FIG. 1, a drying chamber has an upper body and a lower body. The upper body and the lower body are combined with each other to form a treatment space. A bottom surface 1140 forming the treatment space in the lower body has a height difference between a central region 1142 and an edge region 1144. Further, a connection region 1146 that is a gentle inclined surface is formed between the central region 1142 and the edge region 1144. The supercritical fluid introduced into the drying chamber 1000 is introduced between a filler member 1500 and the lower central region 1142, and flows toward a side surface 1160. Thereafter, the supercritical fluid colliding with the side surface 1160 forms an ascending airflow, and the ascending airflow collides with an edge region 1134 of an upper wall of the upper body and then flows toward an upper central region 1132. However, in the above-described structure, a large amount of vortex is generated when the supercritical fluid collides with the edge region 1134 of the upper wall of the upper body.

Due to a large amount of vortex, a large stress is continuously applied to the pattern in the edge region of the upper surface of the substrate W, resulting in a leaning phenomenon in which the pattern is inclined.

### SUMMARY OF THE INVENTION

The present invention has been made in an effort to provide a substrate processing apparatus that prevents a lining phenomenon from occurring in an edge region of a substrate when a substrate is dried with a supercritical fluid.

The present invention has also been made in an effort to provide a substrate processing apparatus that prevents a large amount of vortex from occurring in a specific region of a treatment space in an apparatus that processes a substrate with a supercritical fluid.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a chamber body having a treatment space for processing a substrate; a support unit for supporting a substrate in the treatment space; a fluid supply unit for supplying a supercritical fluid to the treatment space; an exhaust unit for exhausting the supercritical fluid in the treatment space; and a filler member disposed below the substrate supported by the support unit in the treatment space, wherein the treatment space is defined by an upper surface, a bottom surface, and a side surface, the bottom surface has: a lower central region including a region where a first supply port is formed to supply the supercritical fluid supplied by the fluid supply unit to the treatment space; a lower edge region disposed outside the lower central region and positioned higher than the lower central region; and a lower connection region positioned between the lower central region and the lower edge region, when viewed from above, the first supply port overlaps the filler member, and the lower connection region includes a vortex generator that generates a vortex from the supercritical fluid while the supercritical fluid introduced between the filler member and the lower central region flows toward the lower edge region.

According to the exemplary embodiment of the present invention, wherein the vortex generator may include stepped steps to increase a height in a direction from the lower central region toward the lower edge region.

According to the exemplary embodiment of the present invention, wherein a plurality of steps is provided, and the plurality of steps may be provided to gradually increase in height in the direction from the lower central region to the lower edge region.

According to the exemplary embodiment of the present invention, wherein the vortex generator may include a protrusion protruding upwardly in the lower connection region.

According to the exemplary embodiment of the present invention, wherein the lower connection region may be provided as an inclined surface that increases in height toward the lower edge region.

According to the exemplary embodiment of the present invention, wherein the protrusions may be provided to have upper ends having the same height.

According to the exemplary embodiment of the present invention, wherein the protrusions may be provided such that heights of upper ends thereof gradually increase from the lower central region to the lower edge region.

According to the exemplary embodiment of the present invention, wherein an upper end of the protrusion may be provided in a rounded shape that is convex upwardly.

According to the exemplary embodiment of the present invention, wherein the lower central region and the lower edge region are provided as flat surfaces, and an upper end of the protrusion may be provided as a flat surface.

According to the exemplary embodiment of the present invention, wherein the protrusions may be provided in a ring shape.

According to the exemplary embodiment of the present invention, wherein the vortex generator may include a groove formed in the lower connection region.

According to the exemplary embodiment of the present invention, wherein when viewed from above, the lower connection region may be positioned to overlap the substrate supported by the support unit.

According to the exemplary embodiment of the present invention, wherein the upper surface has: an upper central region positioned at a center; and an upper edge region positioned outside the upper central region, and the upper edge region may be positioned higher than the upper central region.

According to the exemplary embodiment of the present invention, wherein the chamber body further includes: an upper body; a lower body combined with the upper body to provide the treatment space; and a driver for moving one of the upper body and the lower body relative to the other so that the treatment space is opened or closed, the first supply port is provided to the lower body, and the upper body may be provided with a second supply port for supplying the supercritical fluid to the treatment space.

According to the exemplary embodiment of the present invention, wherein the support unit may include: a holder installed above the filler member and supporting the substrate loaded into the treatment space; and a support pin installed on an upper surface of the filler member to support the substrate during substrate processing.

An exemplary embodiment of the present disclosure, an apparatus for processing a substrate, the apparatus comprising: a chamber body having a treatment space for processing a substrate; a support unit for supporting a substrate in the treatment space; a fluid supply unit for supplying a fluid to the treatment space; an exhaust unit for exhausting the fluid in the treatment space; and a filler member disposed below the substrate supported by the support unit in the treatment space, wherein the treatment space is defined by an upper surface, a bottom surface, and a side surface, the bottom surface has: a lower central region in which a first supply port is formed to supply the fluid supplied by the fluid supply unit to the treatment space; a lower edge region disposed outside the lower central region and positioned higher than the lower central region; and a lower connection region positioned between the lower central region and the lower edge region, when viewed from above, the first supply port overlaps the filler member, and the bottom surface includes a vortex generator that generates a vortex from the fluid while the fluid introduced between the filler member and the bottom surface flows toward the side surface.

According to the exemplary embodiment of the present invention, wherein the vortex generator may include stepped steps to increase a height in a direction from the lower central region toward the lower edge region.

According to the exemplary embodiment of the present invention, wherein the vortex generator may include a protrusion protruding upwardly or a groove in the lower connection region.

According to the exemplary embodiment of the present invention, wherein the vortex generator may include a protrusion protruding upwardly or a groove in the lower central region.

An exemplary embodiment of the present disclosure, an apparatus for processing a substrate, the apparatus comprising: a lower body; an upper body combined with the lower body to form a treatment space for processing a substrate; a filler member disposed below the substrate supported by a support unit supporting the substrate in the treatment space; a holder installed above the filler member and supporting the substrate loaded into the treatment space; and a support pin installed on an upper surface of the filler member to support the substrate during substrate processing, wherein the treatment space is defined by an upper surface, a bottom surface, and a side surface, the upper surface has: an upper central region positioned at a center; and an upper edge region positioned outside the upper central region, and the upper edge region is provided higher than the upper central region, the bottom surface has: a lower central region in which a first supply port for supplying a supercritical fluid to the treatment space is formed; a lower edge region disposed outside the lower central region and positioned higher than the lower central region; and a lower connection region positioned between the lower central region and the lower edge region, when viewed from above, the first supply port overlaps the filler member, and the connection region overlaps the substrate supported by the support unit when viewed from above, and the connection region includes a vortex generator that generates a vortex from the supercritical fluid while the supercritical fluid introduced between the filler member and the lower central region flows toward the lower edge region, and the vortex generator includes stepped steps to increase a height in a direction from the lower central region toward the lower edge region.

According to the exemplary embodiment of the present invention, it is possible to prevent a lining phenomenon when a substrate is processed.

According to the exemplary embodiment of the present invention, it is possible to weaken the intensity of a descending airflow applied to an end portion of a substrate in a cleaning process using a supercritical fluid.

Effects of the present disclosure are not limited to those described above and effects not stated above will be clearly understood to those skilled in the art from the specification and the accompanying drawings.

### BRIEF DESCRIPTION OF THE DRAWINGS

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a flow of a supercritical fluid in a general process chamber.

FIG. 2 is a top plan view schematically illustrating a substrate processing apparatus according to an exemplary embodiment of the present invention.

FIG. 3 is a diagram schematically illustrating an exemplary embodiment of a liquid treating chamber of FIG. 2.

FIG. 4 is a diagram schematically illustrating the process chamber of FIG. 2 according to the exemplary embodiment.

FIG. 5 is a diagram schematically illustrating the flow of a supercritical fluid in the process chamber according to the exemplary embodiment of FIG. 4.

FIG. 6 is a cross-sectional view schematically illustrating a second exemplary embodiment of a vortex generator of FIG. 4.

FIG. 7 is a diagram schematically illustrating the flow of a supercritical fluid in the process chamber according to the exemplary embodiment of FIG. 6.

FIG. 8 is a diagram schematically illustrating a third exemplary embodiment of the vortex generator of FIG. 4.

FIG. 9 is a diagram schematically illustrating the flow of a supercritical fluid in the process chamber according to the exemplary embodiment of FIG. 8.

FIG. 10 is a diagram schematically illustrating a fourth exemplary embodiment of the vortex generator of FIG. 4.

FIG. 11 is a diagram schematically illustrating the flow of a supercritical fluid in the process chamber according to the exemplary embodiment of FIG. 10.

FIGS. 12 and 13 are diagrams schematically illustrating modified examples of the vortex generator of FIG. 4, respectively.

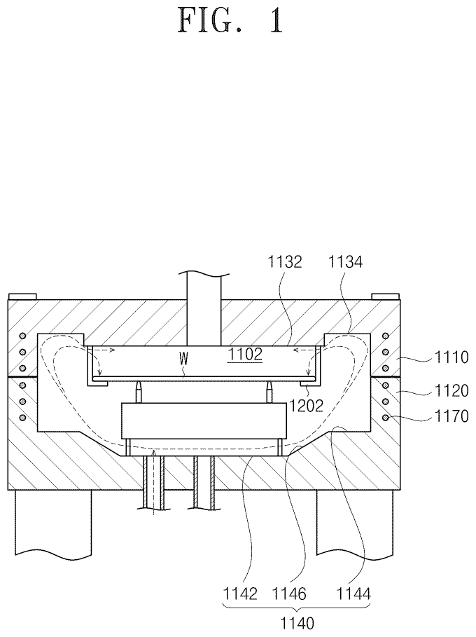

### DETAILED DESCRIPTION

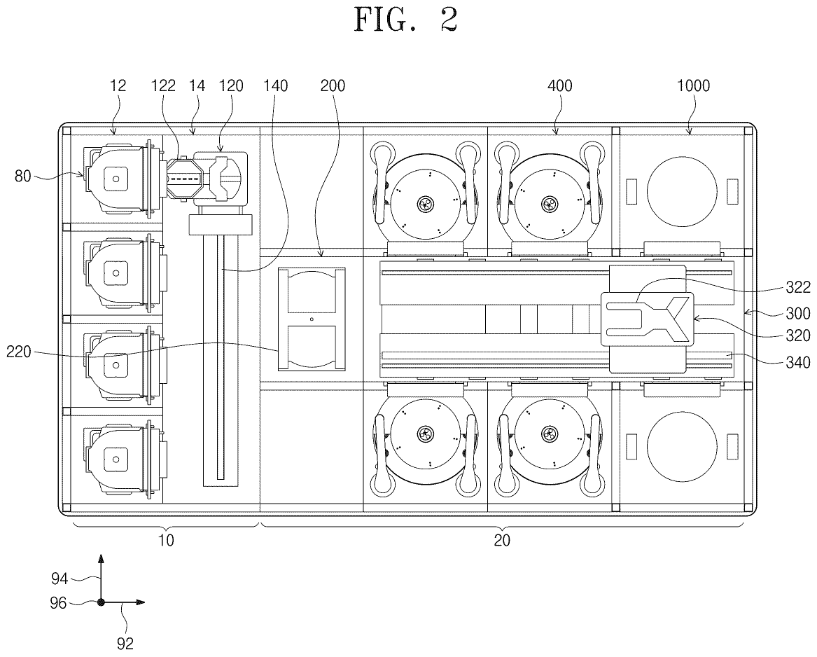

Hereinafter, exemplary embodiment of the present invention will be described with reference to FIGS. 2 to 13.

Hereinafter, a substrate processing apparatus according to the present invention will be described. In an exemplary embodiment of the present invention, a substrate may be a wafer used for manufacturing a semiconductor. However, unlike this, the substrate may be another type of substrate, such as a glass substrate for manufacturing a flat display panel or a mask used for pattern transfer in an exposure process.

FIG. 2 is a top plan view schematically illustrating a substrate processing apparatus according to an exemplary embodiment of the present invention.

Referring to FIG. 2, a substrate processing apparatus 1 includes an index module 10, a treating module 20, and a controller 2. The index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is positioned at a side opposite to the treating module 20. The containers 80 in which the substrates W are accommodated are placed on the load ports 12. The load port 12 may be provided in plural, and the plurality of load ports 12 may be disposed in the second direction 94.

An index robot 120 is provided to the index frame 14. A guide rail 140 of which a longitudinal direction is the second direction 94 is provided within the index frame 14, and the index robot 120 may be provided to be movable along the guide rail 140. The index robot 120 includes a hand 122 on which the substrate W is placed. The hand 122 may be provided to move forward and backward, rotate around the third direction 96, and be movable along the third direction 96. The plurality of hands 122 is provided while being spaced apart from each other in the up and down direction, and is capable of independently moving forward and backward.

The treating module 20 includes a buffer unit 200, a transfer chamber 300, and a process chamber. The process chamber includes a liquid treating chamber 400 and a drying chamber 1000.

The buffer unit 200 provides a space in which the substrate W moved between the index module 10 and the transfer chamber 300 temporarily stays. The liquid treating chamber 400 performs a liquid treating process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction thereof is the first direction 92. The buffer unit 200 may be disposed between the index module 10 and the transfer chamber 300. A plurality of liquid treating chambers 400 is provided. The liquid treating chamber 400 may be disposed on a side portion of the transfer chamber 300. The liquid treating chamber 400 and the transfer chamber 300 may be disposed in the second direction 94. The buffer unit 200 may be positioned at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

The transfer chamber 300 includes a transfer robot 320. A guide rail 340 whose longitudinal direction is provided in the first direction 92 is provided within the transfer chamber 300, and the transfer robot 320 may be provided to be movable on the guide rail 340. The transfer robot 320 includes a hand 322 on which the substrate W is placed. The hand 322 may be provided to move forward and backward, rotate around the third direction 96, and be movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face 201 and a rear face 202 of the buffer unit 200 are opened. The front face 201 of the buffer unit 200 is a face facing the index module 10, and the rear face 202 of the buffer unit 200 is a face facing the transfer chamber 300. The index robot 120 may approach the inside of the buffer unit 200 through the front face 201 of the buffer unit 200, and the transfer robot 320 may approach the buffer unit 200 through the rear face 202 of the buffer unit 200.

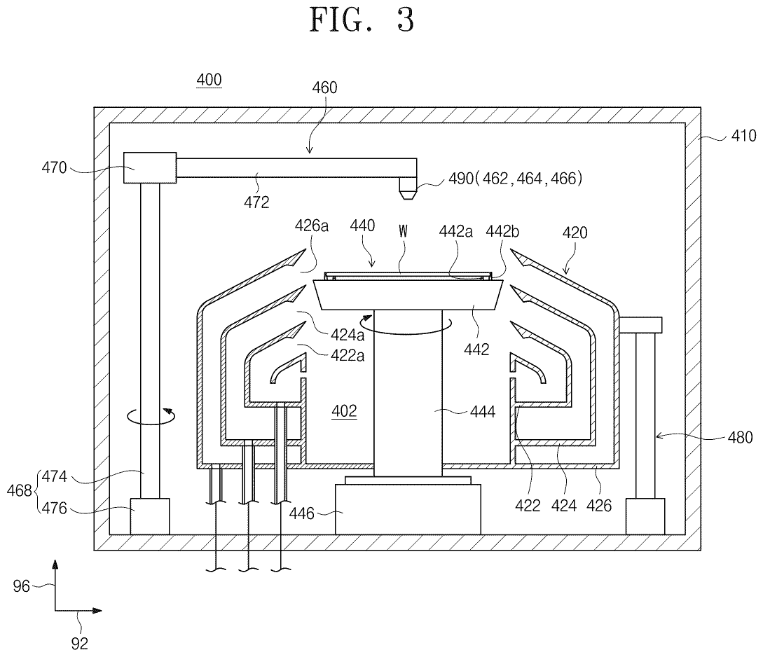

FIG. 3 is a diagram schematically illustrating an exemplary embodiment of the liquid treating chamber of FIG. 2.

Referring to FIG. 3, the liquid treating chamber 400 includes a housing 410, a cup 420, a support unit 440, a nozzle unit 460, and a lifting unit 480.

The housing 410 is provided in a generally rectangular parallelepiped shape. The cup 420, the support unit 440, the nozzle unit 460, and the lifting unit 480 are disposed within the housing 410.

The cup unit 420 has a treatment space 402 in which an upper portion is opened. The cup unit 420 includes an inner cup 422, an intermediate cup 424, and an outer cup 426. The inner cup 422, the intermediate cup 424, and the outer cup 426 each have recovery spaces for recovering a liquid used for processing the substrate W. The inner cup 422, the intermediate cup 424, and the outer cup 426 are each provided in a ring shape surrounding the support unit 440. When the liquid treating process is performed, the treatment liquid scattered by rotation of the substrate W flows into the recovery spaces through the inlets 422a, 424a, and 426a of the inner cup 422, the intermediate cup 424, and the outer cup 426. According to the exemplary embodiment, the inner cup 422 is disposed to surround the support unit 440, the intermediate cup 424 is disposed to surround the inner cup 422, and the outer cup 426 is disposed to surround the intermediate cup 424. The intermediate cup inlet 424a through which the liquid flows into the intermediate cup 424 may be positioned above the inner cup inlet 422a through which the liquid flows into the inner cup 422, and the outer cup inlet 426a through which the liquid flows into the outer cup 426 may be positioned above the intermediate cup inlet 424a through which the liquid flows into the intermediate cup 424.

The support unit 440 supports the substrate W in the treatment space 402. The support unit 440 includes a spin chuck 442 and a drive shaft 444. An upper surface of the spin chuck 442 may be provided in a generally circular shape, and may have a diameter larger than a diameter of the substrate W. A chuck pin 442b is provided at an edge of the spin chuck 442. The chuck pin 442b is provided to protrude upwardly from the spin chuck 442. The chuck pin 442b supports a side portion of the substrate W so that the substrate W does not deviate from the support unit 440 when the substrate W is rotated. Also, a support pin 442a is provided to the spin chuck 442. The support pin 442a is provided with a top end protruding from the spin chuck 442 such that the substrate W is spaced a certain distance from the spin chuck 442. The support pin 442a is disposed closer to a center of the spin chuck 442 than the chuck pin 442b. The drive shaft 444 is driven by the driver 446, is connected to a center of a bottom surface of the substrate W, and rotates the spin chuck 442 with respect to its central axis.

The nozzle unit 460 supplies a treatment liquid onto the substrate W supported on the support unit 440. The treatment liquid may be provided in a plurality of types, and may be sequentially supplied onto the substrate W. The nozzle unit 460 includes a support frame 470, an arm 472, a first nozzle 462, a second nozzle 464, a third nozzle 466, and a nozzle driver 468.

The first nozzle 462 supplies a first treatment liquid onto the substrate W. The second nozzle 464 supplies a second treatment liquid onto the substrate W. The third nozzle 466 supplies the third treatment liquid onto the substrate W. The first treatment liquid, the second treatment liquid, and the third treatment liquid are different types of treatment liquids. The first treatment liquid, the second treatment liquid, and the third treatment liquid may be an acidic component, an alkali component, or a neutral component. For example, the first treatment liquid, the second treatment liquid, and the third treatment liquid may be an acid component, such as sulfuric acid, hydrofluoric acid, phosphoric acid, or hydrochloric acid, or may be an alkali component, such as ammonia, or water.

Meanwhile, a nozzle unit 460 for supplying another type of treatment liquid may be further provided. For example, the nozzle unit 460 may further include a nozzle for supplying an organic solvent, such as isopropyl alcohol (IPA).

The support frame 470 supports the arm 472. A plurality of arms 472 is provided so that each nozzle 490 is installed. Each nozzle 490 is installed at an end of the arm 472. The arm 472 is provided side by side in one direction. The nozzle driver 468 has a drive shaft 474 and a driver 476. The nozzle driver 468 drives the support frame 470 such that the nozzles 490 move between a process position and a standby position R. The process position is a position at which the nozzle 490 supplies the treatment liquid onto the substrate W. The standby position is a position at which the nozzle 490 which has completed supplying the treatment liquid onto the substrate W waits until the next processing of the substrate W.

The lifting unit 480 adjusts a relative height between the cup 420 and the support unit 440. According to an example, the lifting unit 480 moves the cup 420 in the vertical direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the treatment liquids may be separated and recovered. Unlike the description, the cup 420 may be fixedly installed, and the lifting unit 480 may move the support unit 440 in the vertical direction.

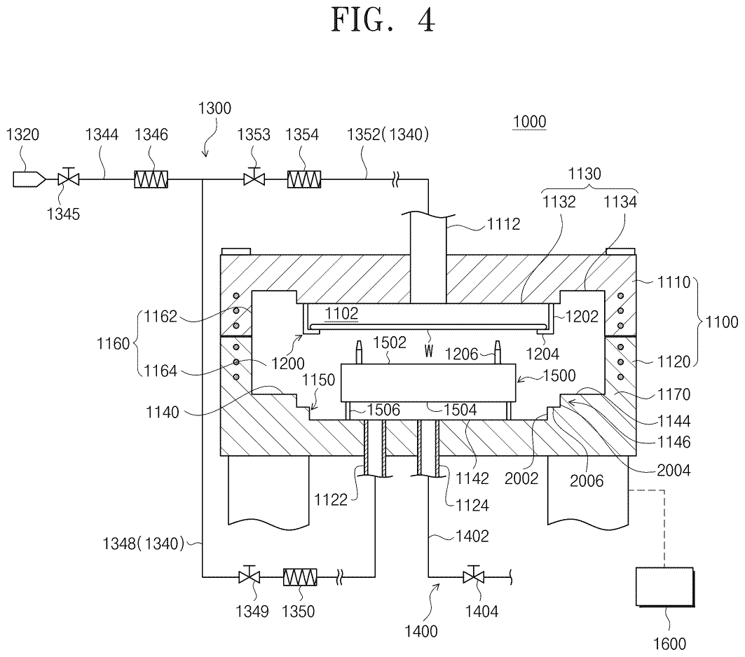

FIG. 4 is a diagram schematically illustrating the drying chamber of FIG. 2 according to the exemplary embodiment.

Referring to FIG. 4, the drying chamber 1000 includes a chamber body 1100, a filler member 1500, a support unit 1200, a driver 1600, a fluid supply unit 1300, and an exhaust unit 1400. The drying chamber 1000 performs a process of removing a liquid on the substrate W by using a supercritical fluid.

The body 1100 provides a treatment space 1102 in which a drying process is performed. The body 1100 includes an upper body 1110 and a lower body 1120. The upper body 1110 and the lower body 1120 are combined to form the treatment space 1102. The upper body 1110 is provided on the lower body 1120. The lower body 1120 is relatively moved from the upper body 1110. Alternatively, the upper body 1110 is relatively moved from the lower body 1120. As the lower body 1120 or the upper body 1110 is moved relative to the other one, the treatment space 1102 is opened or closed. As the treatment space 1102 is opened, the substrate W may be loaded in or unloaded. According to the exemplary embodiment, a position of the upper body 1110 is fixed, and the lower body 1120 may be raised or lowered by the driver 1600. According to the exemplary embodiment, the driver 1600 may be provided as a cylinder. During the process, the upper body 1110 and the lower body 1120 are in close contact with each other so that the treatment space 1102 is sealed from the outside.

The treatment space 1102 is defined by an upper surface 1130, a bottom surface 1140, and a side surface 1160 of the chamber body 1100. The upper surface 1130 is formed by a lower surface of the upper body 1110. The bottom surface 1140 is formed by an upper surface of the lower body 1120. Further, the side surface 1160 is formed by a combination of the inner surface of the upper body 1110 and the inner surface of the lower body 1120.

The upper surface 1130 has an upper central region 1132 and an upper edge region 1134. The upper edge region 1134 is a region surrounding the upper central region 1132 outside the upper central region 1132. The upper edge region 1134 is positioned higher than the upper central region 1132. That is, the upper edge region 1134 and the upper central region 1132 are provided to be stepped.

The bottom surface 1140 includes a lower central region 1142, a lower edge region 1144, and a lower connection region 1146. The lower central region 1142 is provided in a central portion of the bottom surface 1140. The lower central region 1142 includes a region of the bottom surface 1140 in which a first supply port 1122 to be described later is provided, and a region adjacent thereto. The lower edge region 1144 is provided outside the lower central region 1142. The lower edge region 1144 is positioned higher than the lower central region 1142. The lower central region 1142 and the lower edge region 1144 are each provided as flat surfaces. For example, the lower central region 1142 and the lower edge region 1144 are provided in parallel with respect to the substrate W supported by the support unit 1200. The lower connection region 1146 is provided between the lower central region 1142 and the lower edge region 1144. The lower connection region 1146 connects the lower central region 1142 and the lower edge region 1144. The lower connection region 1146 includes a vortex generator 1150.

The side surface 1160 includes a side upper region 1162 and a side lower region 1164. The side upper region 1162 is provided inside the upper body 1110, and the side lower region 1164 is provided inside the lower body 1120.

The lower body 1120 is provided with a first supply port 1122 and an exhaust port 1124. When viewed from above, the first supply port 1122 is provided eccentrically from the center of the lower body 1120. The first supply port 1122 is formed in the lower central region 1142. The exhaust port 1124 is formed in the center of the lower body 1120 when viewed from above.

A second supply port 1112 is formed in the upper body 1110. The second supply port 1112 is formed at the center of the upper body 1110.

The supercritical fluid is supplied to the treatment space 1102 through the first supply port 1122 or the second supply port 1112. The supercritical fluid in the treatment space 1102 is exhausted to the outside of the drying chamber 1000 through the exhaust port 1124.

The supercritical fluid supplied through the first supply port 1122 is supplied to a region of the treatment space 1102 lower than the substrate W. The supercritical fluid supplied through the second supply port 1112 is supplied to a region of the treatment space 1102 higher than the substrate W.

The heater 1170 is installed in the body 1100. According to the exemplary embodiment, the heater 1170 is positioned inside a wall of the body 1100. The heater 1170 heats the treatment space 1102 so that the fluid supplied to the treatment space 1102 of the body 1100 maintains a supercritical state.

The filler member 1500 is disposed in the treatment space 1102. The filler member 1500 is supported by the support 1506 to be spaced apart upwardly from the bottom surface of the lower body 1110. The support 1506 is provided in a rod shape. A plurality of supports 1506 is disposed to be spaced apart from each other by a predetermined distance. When viewed from above, the filler member 1500 is disposed to overlap the first supply port 1122 and the exhaust port 1124. The filler member 1500 prevents the substrate W from being damaged by discharging the supercritical fluid supplied through the first line 1348 directly toward the back surface of the substrate W. The filler member 1500 occupies a volume within the treatment space 1102. The filler member 1500 is provided to have a constant thickness. Accordingly, when the supercritical fluid is supplied to the treatment space 1102, the treatment space 1102 may be rapidly pressurized. An upper surface 1502 of the filler member is positioned higher than the lower edge region 1144. According to the exemplary embodiment, a lower surface 1504 of the filler member may be positioned lower than the lower edge region 1144.

The support unit 1200 includes a substrate holder and a support pin 1206. The substrate holder has a fixed rod 1202 and a holder 1204. The support unit 1200 supports the substrate W in the treatment space 1102.

The fixed rod 1202 is fixedly installed on the upper body 1110 so as to protrude downward from the bottom surface of the upper body 1110. The fixed rod 1202 is provided in a vertical direction in its longitudinal direction. A plurality of fixed rods 1202 is provided and is positioned to be spaced apart from each other. The fixed rods 1202 are disposed at positions where the substrate W does not interfere with the fixed rods 1202 when the substrate W is loaded in or unloaded from a space surrounded by the fixed rods 1202. The holder 1204 is coupled to each fixed rod 1202.

The holder 1204 extends in a direction from a lower end of the fixed rod 1202 toward a space surrounded by the fixed rods 1202. The holder 1204 is provided in a direction perpendicular to the fixed rod 1202. The holder 1204 supports the substrate W when the substrate W is loaded or unloaded.

The support pin 1206 is installed on the upper surface 1502 of the filler member 1500. The support pin 1206 is disposed to overlap the central region of the substrate W seated on the holder 1204. After the substrate W is loaded into the treatment space 1102, is seated on the holder 1204, and the drying chamber 1000 is sealed, and then the support pin 1206 supports the substrate W as the lower body 1120 moves upwardly by the driver.

The fluid supply unit 1300 supplies a supercritical fluid to the treatment space 1102. Here, supplying the supercritical fluid means supplying a fluid that is phase transited to a supercritical state to process the substrate W. Therefore, supplying the supercritical fluid includes not only supplying the fluid in the supercritical state directly to the treatment space 1102, but also supplying gas or a fluid in the subcritical state to the treatment space 1102, and changing the phase to the supercritical state in the treatment space 1102. According to the exemplary embodiment, the supercritical fluid is supplied to the treatment space 1102 in the supercritical state.

The fluid supply unit 1300 includes a fluid supply source 1320, and a fluid supply line 1340.

The fluid supply source 1320 is provided as a supply tank. The fluid supply source 1320 stores a fluid therein. According to the exemplary embodiment, the fluid supply source 1320 may store a fluid in a supercritical state inside thereof. According to the exemplary embodiment, the fluid stored in the fluid supply source 1320 may be carbon dioxide (CO₂).

The fluid supply line 1340 includes a main supply line 1344, a first line 1348, and a second line 1352. The main supply line 1344 is connected to the fluid supply source 1320 side. The main supply line 1344 is branched to the first line 1348 and the second line 1352. The first line 1348 connects the main supply line 1344 to the first supply port 1122 of the lower body 1110. The first line 1348 supplies the supercritical fluid to a position lower than the substrate W in the treatment space 1102. The second line 1352 connects the main supply line 1344 to the second supply port 1112 of the upper body 1110. The second line 1352 supplies the supercritical fluid to a position higher than the substrate W in the treatment space 1102.

A main valve 1345 and a main heater 1346 are installed in the main supply line 1344. The main valve 1345 opens and closes the inside of the main supply line 1344. The main heater 1346 is installed downstream from the main valve 1345. The main heater 1346 heats the inside of the main supply line 1344. The first valve 1349 and the first heater 1350 are installed in the first line 1348. The first valve 1349 opens and closes the inside of the first line 1348. The first heater 1350 heats the inside of the first line 1348. The first heater 1350 is installed downstream from the first valve 1349. A second valve 1353 and a second heater 1354 are installed in the second line 1352. The second valve 1353 opens and closes the inside of the second line 1352. The second heater 1354 heats the inside of the second line 1352. The second heater 1354 is installed downstream from the second valve 1353.

The exhaust unit 1400 includes an exhaust line 1402. The exhaust line 1402 is connected to the exhaust port 1124. An exhaust valve 1404 is installed on the exhaust line 1402. The exhaust valve 1404 opens and closes the inside of the exhaust line 1402.

During the drying treatment, a pressurizing process, a processing process, and a depressurizing process are sequentially performed.

The pressurizing process is a process of increasing the pressure by supplying the supercritical fluid to the treatment space 1102. In the pressurizing process, the supercritical fluid is supplied to the lower portion of the treatment space 1102 through the first line 1348. After the pressurizing process is terminated, the processing process is performed. The processing process is a process of drying the substrate W by supplying the supercritical fluid from the treatment space 1102. In the processing process, the supercritical fluid is supplied to the upper portion of the treatment space 1102 through the second line 1352. In this case, the supercritical fluid may be pulse-supplied or constantly supplied. After the processing process is terminated, the depressurizing process is performed. The depressurizing process is a process of discharging the supercritical fluid from the treatment space 1102 to the outside. In the depressurizing process, the supercritical fluid is discharged through the exhaust line 1402. The depressurizing process is a process of discharging the supercritical fluid from the treatment space 1102 to the outside. In the depressurizing process, the supercritical fluid is discharged through the exhaust line 1402.

A vortex generator 1150 is provided on the bottom surface 1140. The vortex generator 1150 forms a small vortex when the supercritical fluid supplied through the first line 1348 flows along the bottom surface 1140. According to the exemplary embodiment, the vortex generator 1150 is provided in the lower connection region 1146.

According to an example, the vortex generator 1150 includes stepped steps. For example, two steps may be formed from the lower central region 1142 to the lower edge region 1144.

The lower connection region 1146 includes a first sidewall 2002, a bottom 2006, and a second sidewall 2004. The first sidewall 2002, the bottom 2006, and the second sidewall 2004 are positioned sequentially and continuously in a direction from the lower central region 1142 toward the lower edge region 1144.

Hereinafter, a process of supplying a supercritical fluid through the first supply port will be described. In the drawings below, a dotted line illustrated in the treatment space represents the flow of the supercritical fluid.

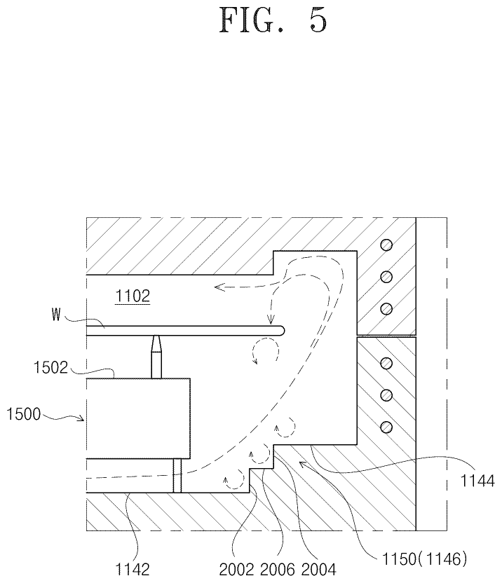

FIG. 5 is a diagram schematically illustrating the flow of a supercritical fluid in the process chamber according to the exemplary embodiment of FIG. 4.

Referring to FIG. 5, the supercritical fluid is introduced into the treatment space 1102 through the first supply port 1122. The vortex generator 1150 generates a vortex from the supercritical fluid while the supercritical fluid introduced between the filler member 1500 and the lower central region 1142 flows toward the lower edge region 1144. When the supercritical fluid passes from the lower central region 1142 to the upper portion of the lower connection region 1146, some of the supercritical fluid collides with the first sidewall 2002 and the second sidewall 2004. A small amount of the vortex is generated between the first sidewall 2002 and the lower central region 1142, and between the bottom 2006 and the second sidewall 2004.

A small amount of vortexes disperses the vortexes to be formed in the outer region of the treatment space 1102. As the intensity of the vortex weakens, the intensity of the descending airflow of the supercritical fluid applied to the end of the upper surface of the substrate W decreases. In addition, since a small amount of vortexes is generated in the vortex generator 1150, a large amount of vortex may be prevented from being generated in the upper edge region 1134. Accordingly, it is possible to prevent the occurrence of the lining phenomenon.

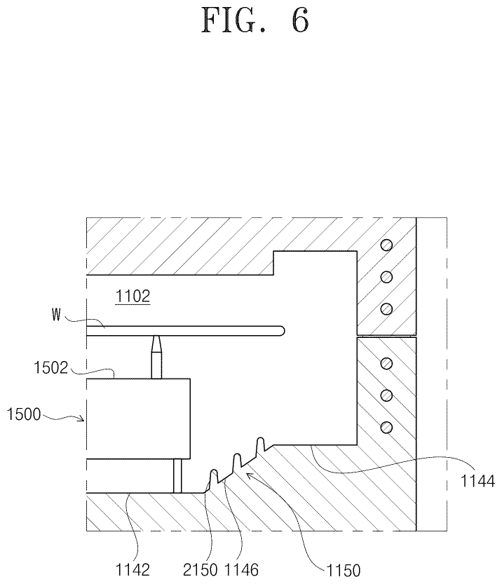

FIG. 6 is a cross-sectional view schematically illustrating a second exemplary embodiment of the vortex generator of FIG. 4.

Referring to FIG. 6, the lower connection region 1146 is provided as an inclined surface whose height increases from the lower central region 1142 to the lower edge region 1144. The vortex generator 1150 includes protrusions 2150 protruding upwardly from the lower connection region 1146. The upper end of the protrusion 2150 is provided in a rounded shape that is convex upwardly.

A plurality of protrusions 2150 is provided. Each of the protrusions 2150 is provided to have a constant height from the inclined surface. That is, the upper ends of the protrusions 2150 are provided so that the heights thereof increase from the lower central region 1142 to the lower edge region 1144. According to the exemplary embodiment, the protrusion 2150 provided at the lowest position in the inclined surface may be positioned to be adjacent to the lower central region 1142, and the protrusion 2150 provided at the highest position may be positioned to be adjacent to the lower edge region 1144. The protrusions 2150 are disposed to be spaced apart from each other by a predetermined distance. The protrusions 2150 are provided in a ring shape when viewed from above. For example, the protrusions 2150 may be provided in a plurality of ring shapes forming a concentric circle.

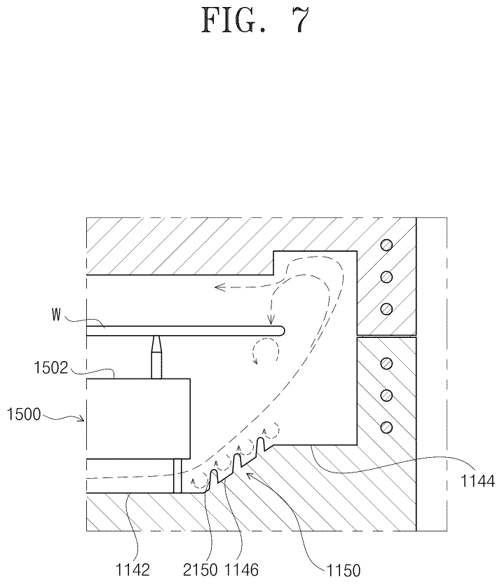

FIG. 7 is a diagram schematically illustrating the flow of a supercritical fluid in the process chamber according to the exemplary embodiment of FIG. 6.

Referring to FIG. 7, when the supercritical fluid passes through the upper portion of the lower connection region 1146 in which the protrusion 2150 is formed in the lower central region 1142, some of the supercritical fluid collides with the protrusion 2150. The supercritical fluid colliding with the protrusion 2150 descends toward the lower connection region 1146. By the flow, a small amount of vortexes is formed in a region between the protrusions 2150 in the upper region of the lower connection region 1146.

A small amount of vortexes disperses the vortexes to be formed in the outer region of the treatment space 1102. As the intensity of the vortex weakens, the intensity of the descending airflow of the supercritical fluid applied to the end of the upper surface of the substrate W decreases. In addition, since a small amount of vortexes is generated in the vortex generator 1150, a large amount of vortex may be prevented from being generated in the upper edge region 1134. Accordingly, it is possible to prevent the occurrence of the lining phenomenon.

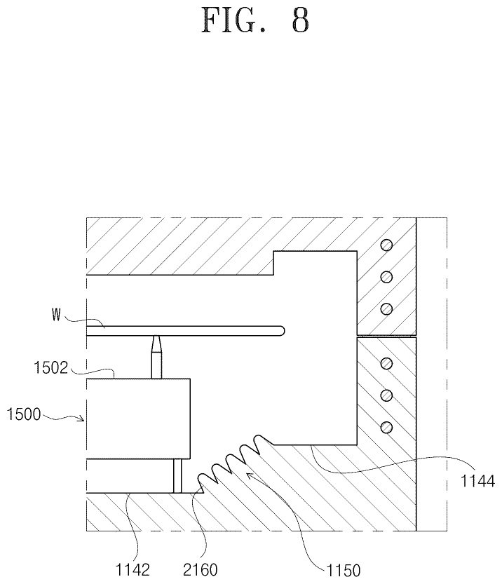

FIG. 8 is a diagram schematically illustrating a third exemplary embodiment of the vortex generator of FIG. 4.

Referring to FIG. 8, as in the exemplary embodiment of FIG. 6, the lower connection region 1146 is provided as an inclined surface. The vortex generator 1150 includes protrusions 2160 protruding from the lower connection region 1146 in a direction perpendicular to the inclined surface. That is, the protrusion 2160 is provided to be inclined toward the lower central region 1142. The upper end of the protrusion 2160 is provided in a rounded shape that is convex upwardly.

A plurality of protrusions 2160 is provided. Each of the protrusions 2160 is provided to have a constant height from the inclined surface. According to the exemplary embodiment, the protrusion 2160 provided at the lowest position may be provided to be in contact with the lower central region 1142, and the protrusion 2160 provided at the highest position may be provided to be in contact with the lower edge region 1144. Each of the protrusions 2160 is provided such that its lower ends are in contact with each other. Each of the protrusions 2160 is provided in a ring shape when viewed from above. For example, the protrusions 2160 may be provided in a plurality of ring shapes forming a concentric circle.

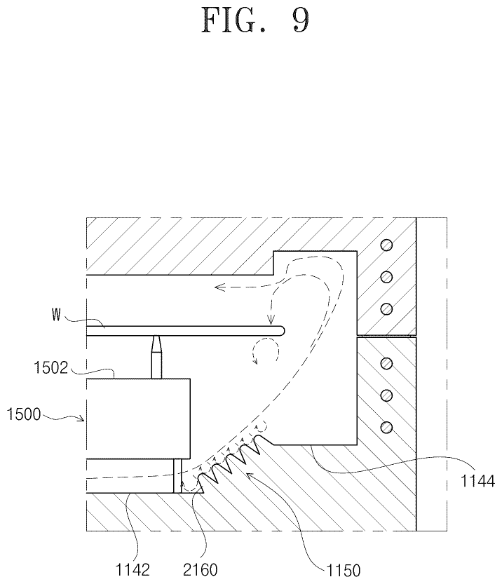

FIG. 9 is a diagram schematically illustrating the flow of a supercritical fluid in the process chamber according to the exemplary embodiment of FIG. 8.

Referring to FIG. 9, when the supercritical fluid passes through the upper portion of the lower connection region 1146 in which the protrusions 2160 are formed in the lower central region 1142, some of the supercritical fluid collides with the protrusions 2160. The supercritical fluid colliding with the protrusion 2160 descends toward the lower connection region 1146. By the flow, a small amount of vortexes is formed in a region between the protrusions 2160 in the upper region of the lower connection region 1146.

A small amount of vortexes disperses the vortexes to be formed in the outer region of the treatment space 1102. As the intensity of the vortex weakens, the intensity of the descending airflow of the supercritical fluid applied to the end of the upper surface of the substrate W decreases. In addition, since a small amount of vortexes is generated in the vortex generator 1150, a large amount of vortex may be prevented from being generated in the upper edge region 1134. Accordingly, it is possible to prevent the occurrence of the lining phenomenon.

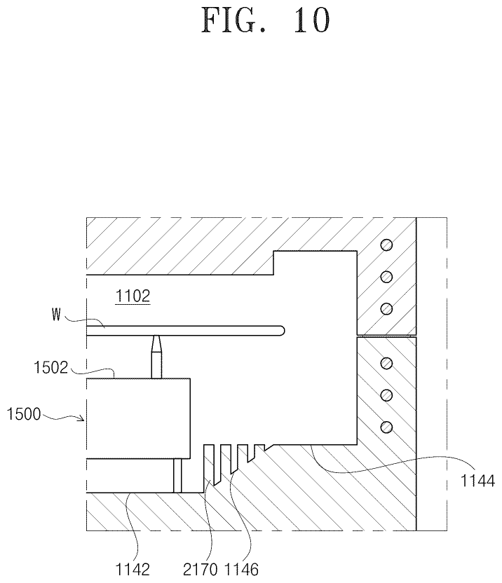

FIG. 10 is a diagram schematically illustrating a fourth exemplary embodiment of the vortex generator of FIG. 4.

Referring to FIG. 10, the lower connection region 1146 is provided as an inclined surface whose height increases from the lower central region 1142 to the lower edge region 1144. The vortex generator 1150 includes a protrusion 2170 protruding upwardly from the lower connection region 1146. The upper end of the protrusion 2170 is provided as a flat surface. For example, the upper end of the protrusion 2170 may be provided in parallel respect to the lower edge region 1144. A sidewall of the protrusion 2170 is provided perpendicular to the upper end of the protrusion 2170. According to an exemplary embodiment, the protrusion 2170 may have a height longer than the width thereof. For example, the protrusion 2170 may be a thin wall provided in a direction perpendicular to the lower central region 1142.

A plurality of protrusions 2170 is provided. The heights of the upper ends of the protrusions 2170 have the same height. That is, each of the protrusions 2170 is provided to have a lower height from the lower central region 1142 to the lower edge region 1144. According to an exemplary embodiment, the protrusion 2170 provided at the lowest position in the inclined surface may be provided to be in contact with the lower central region 1142, and the protrusion 2170 provided at the highest position may be provided to be in contact with the lower edge region 1144. The protrusions 2170 are disposed to be spaced apart from each other by a predetermined distance. The protrusions 2170 are provided in a ring shape when viewed from above. For example, the protrusions 2170 may be provided in a plurality of ring shapes forming a concentric circle.

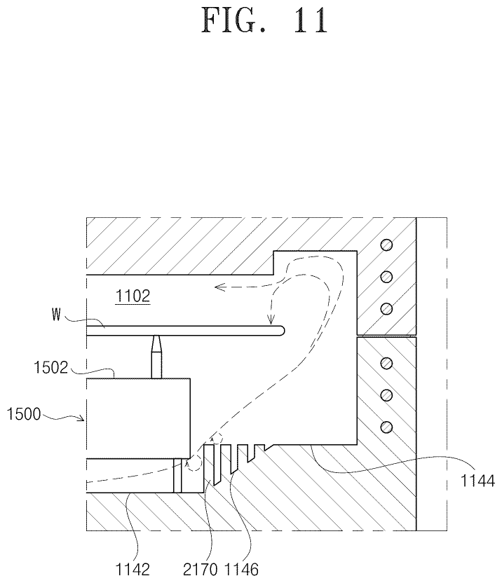

FIG. 11 is a diagram schematically illustrating the flow of a supercritical fluid in the process chamber according to the exemplary embodiment of FIG. 10.

When the supercritical fluid passes through the upper portion of the lower connection region 1146 in which the protrusion 2170 is formed in the lower central region 1142, some of the supercritical fluid collides with the protrusion 2170. The supercritical fluid colliding with the protrusion 2170 descends toward the lower connection region 1146. By the flow, a small amount of vortexes is formed in a region between the protrusions 2170 in the upper region of the lower connection region 1146.

A small amount of vortexes disperses the vortexes to be formed in the outer region of the treatment space 1102. As the intensity of the vortex weakens, the intensity of the descending airflow of the supercritical fluid applied to the end of the upper surface of the substrate W decreases. In addition, since a small amount of vortex is generated in the vortex generator 1150, a large amount of vortex may be prevented from being generated in the upper edge region 1134. Accordingly, it is possible to prevent the occurrence of the lining phenomenon.

Hereinafter, various modified examples of the substrate processing apparatus according to the present invention will be described.

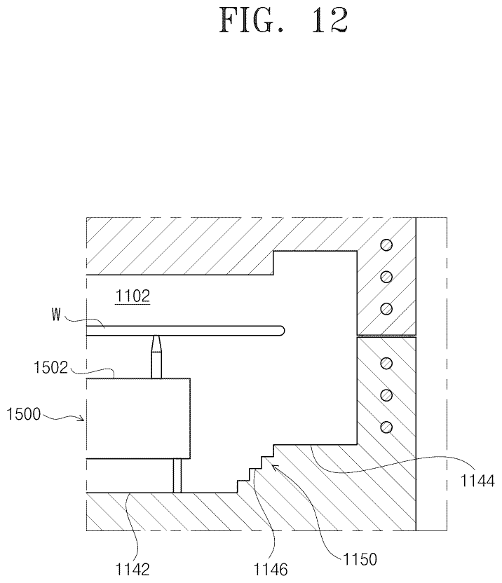

In the vortex generator 1150 according to the first exemplary embodiment described above, two steps are formed from the lower central region 1142 to the lower edge region 1144. However, the present invention is not limited thereto. For example, as shown in FIG. 12, the vortex generator may be provided as steps in which a plurality of steps is formed. With this structure, more small vortexes may be formed, and the vortexes formed in the edge region of the upper treatment space 1102 may be weakened.

In the above-described second exemplary embodiment, the present invention has been described that the protrusions are provided at the same height. However, unlike this, the protrusions may be provided at different heights. For example, the protrusion may be formed such that the height of the upper end thereof is gradually increased in a direction toward the upper portion from the lower connection region.

In the above-described fourth exemplary embodiment, the protrusions 2170 have different heights from the inclined surface and have flat upper ends, but the present invention is not limited thereto. The protrusion 2170 may have a predetermined height from the inclined surface and may have a flat upper end.

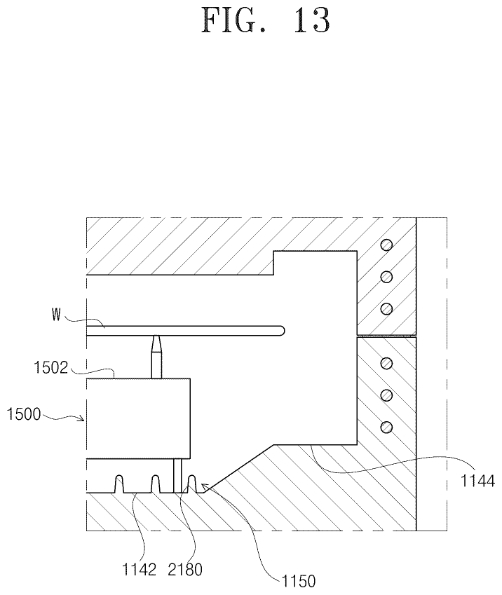

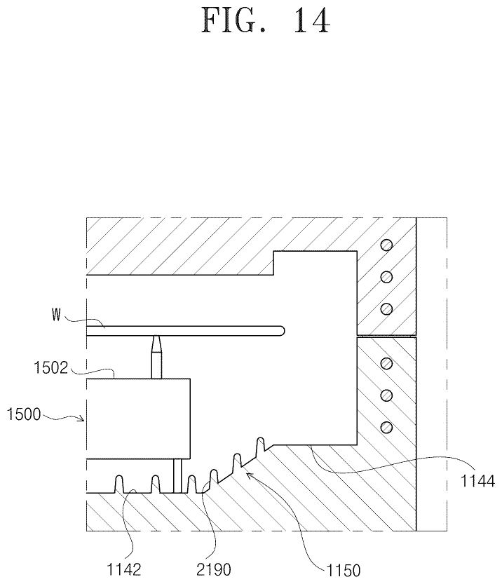

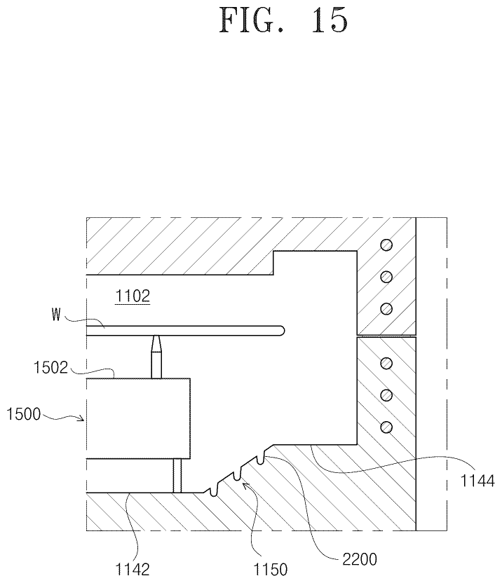

In the above-described exemplary embodiment, the present invention has been described that the vortex generator 1150 is provided to the lower connection region 1146, but the present invention is not limited thereto. The vortex generator 2150 may be formed in the lower central region 1142 as shown in FIG. 13. Optionally, the protrusions 2190 may be formed in the lower central region 1142 and the lower connection region 1146, as shown in FIG. 14.

In the above exemplary embodiments, the present invention has been described that the upper surface 1502 of the filler member is positioned higher than the lower edge region 1144. However, the present invention is not limited thereto. For example, the height of the upper surface 1502 of the filler member may coincide with the height of the lower edge region 1144, or may be positioned lower than the height of the lower edge region 1144.

In the above exemplary embodiment, it has been described that the upper surface 1130 includes an upper edge region 1134 and an upper central region 1132, and the upper edge region 1134 is positioned higher than the upper central region 1132. However, this is illustrative and the present invention is not limited thereto. For example, the upper surface 1130 may be provided in a flat structure without a step difference.

In the second to fourth exemplary embodiments described above, the present invention has been described that the vortex generator 1150 includes the plurality of protrusions 2150, 2160, and 2170. However, this is illustrative and the present invention is not limited thereto. The vortex generator 1150 may include only one protrusion 2150, 2160, and 2170.

In the above exemplary embodiment, the vortex generator 1150 is provided in a stepwise or protrusion shape. However, this is illustrative and the present invention is not limited thereto. Referring to FIG. 15, the vortex generator 1150 may be provided as a groove 2200 formed in the bottom surface 1140. According to the exemplary embodiment, the groove 2200 may be formed in the lower connection region 1146. According to another exemplary embodiment, the groove 2200 may be formed over the lower connection region 1146 and the lower central region 1142. Optionally, the groove 2200 may be formed only in the lower central region 1142.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
a chamber body having a treatment space for processing a substrate;
a support unit for supporting a substrate in the treatment space;
a fluid supply unit for supplying a supercritical fluid to the treatment space;
an exhaust unit for exhausting the supercritical fluid in the treatment space; and
a filler member disposed below the substrate supported by the support unit in the treatment space,
wherein the treatment space is defined by an upper surface, a bottom surface, and a side surface,
the bottom surface has:
a lower central region including a region where a first supply port is formed to supply the supercritical fluid supplied by the fluid supply unit to the treatment space;
a lower edge region disposed outside the lower central region and positioned higher than the lower central region; and
a lower connection region positioned between the lower central region and the lower edge region,
when viewed from above, the first supply port overlaps the filler member, and
the lower connection region includes a vortex generator that generates a vortex from the supercritical fluid while the supercritical fluid introduced between the filler member and the lower central region flows toward the lower edge region.

2. The apparatus of claim 1, wherein the vortex generator includes stepped steps to increase a height in a direction from the lower central region toward the lower edge region.

3. The apparatus of claim 2, wherein a plurality of steps is provided, and
the plurality of steps is provided to gradually increase in height in the direction from the lower central region to the lower edge region.

4. The apparatus of claim 1, wherein the vortex generator includes a protrusion protruding upwardly in the lower connection region.

5. The apparatus of claim 4, wherein the lower connection region is provided as an inclined surface that increases in height toward the lower edge region.

6. The apparatus of claim 4, wherein the protrusions are provided to have upper ends having the same height.

7. The apparatus of claim 4, wherein the protrusions are provided such that heights of upper ends thereof gradually increase from the lower central region to the lower edge region.

8. The apparatus of claim 4, wherein an upper end of the protrusion is provided in a rounded shape that is convex upwardly.

9. The apparatus of claim 4, wherein the lower central region and the lower edge region are provided as flat surfaces, and
an upper end of the protrusion is provided as a flat surface.

10. The apparatus of claim 4, wherein the protrusions are provided in a ring shape.

11. The apparatus of claim 1, wherein the vortex generator includes a groove formed in the lower connection region.

12. The apparatus of claim 1, wherein when viewed from above, the lower connection region is positioned to overlap the substrate supported by the support unit.

13. The apparatus of claim 1, wherein the upper surface has:
an upper central region positioned at a center; and
an upper edge region positioned outside the upper central region, and
the upper edge region is positioned higher than the upper central region.

14. The apparatus of claim 1, wherein the chamber body further includes:
an upper body;
a lower body combined with the upper body to provide the treatment space; and
a driver for moving one of the upper body and the lower body relative to the other so that the treatment space is opened or closed,
the first supply port is provided to the lower body, and
the upper body is provided with a second supply port for supplying the supercritical fluid to the treatment space.

15. The apparatus of claim 14, wherein the support unit includes:
a holder installed above the filler member and supporting the substrate loaded into the treatment space; and
a support pin installed on an upper surface of the filler member to support the substrate during substrate processing.

16. An apparatus for processing a substrate, the apparatus comprising:
a chamber body having a treatment space for processing a substrate;
a support unit for supporting a substrate in the treatment space;
a fluid supply unit for supplying a fluid to the treatment space;
an exhaust unit for exhausting the fluid in the treatment space; and
a filler member disposed below the substrate supported by the support unit in the treatment space,
wherein the treatment space is defined by an upper surface, a bottom surface, and a side surface,
the bottom surface has:
a lower central region in which a first supply port is formed to supply the fluid supplied by the fluid supply unit to the treatment space;
a lower edge region disposed outside the lower central region and positioned higher than the lower central region; and
a lower connection region positioned between the lower central region and the lower edge region,
when viewed from above, the first supply port overlaps the filler member, and
the bottom surface includes a vortex generator that generates a vortex from the fluid while the fluid introduced between the filler member and the bottom surface flows toward the side surface.

17. The apparatus of claim 16, wherein the vortex generator includes stepped steps to increase a height in a direction from the lower central region toward the lower edge region.

18. The apparatus of claim 16, wherein the vortex generator includes a protrusion protruding upwardly or a groove in the lower connection region.

19. The apparatus of claim 16, wherein the vortex generator includes a protrusion protruding upwardly or a groove in the lower central region.

20. An apparatus for processing a substrate, the apparatus comprising:
a lower body;
an upper body combined with the lower body to form a treatment space for processing a substrate;
a filler member disposed below the substrate supported by a support unit supporting the substrate in the treatment space;
a holder installed above the filler member and supporting the substrate loaded into the treatment space; and
a support pin installed on an upper surface of the filler member to support the substrate during substrate processing,
wherein the treatment space is defined by an upper surface, a bottom surface, and a side surface,
the upper surface has:
an upper central region positioned at a center; and
an upper edge region positioned outside the upper central region, and
the upper edge region is provided higher than the upper central region,
the bottom surface has:
a lower central region in which a first supply port for supplying a supercritical fluid to the treatment space is formed;
a lower edge region disposed outside the lower central region and positioned higher than the lower central region; and
a lower connection region positioned between the lower central region and the lower edge region,
when viewed from above, the first supply port overlaps the filler member, and
the connection region overlaps the substrate supported by the support unit when viewed from above, and
the connection region includes a vortex generator that generates a vortex from the supercritical fluid while the supercritical fluid introduced between the filler member and the lower central region flows toward the lower edge region, and
the vortex generator includes stepped steps to increase a height in a direction from the lower central region toward the lower edge region.
